(19) United States
(12) Patent Application Publication
(10) Pub. No.: US 2026/0157131 A1
(43) Pub. Date: Jun. 4, 2026

(54) METHOD FOR FILLING A HIGH ASPECT RATIO TRENCH

(71) Applicant: STMicroelectronics International N.V., Geneva (CH)

(72) Inventors: Francesco DI STEFANO, Singapore (SG); Fadhillawati TAHIR, Singapore (SG); Voon Cheng NGWAN, Singapore (SG); Winnie Chen Sing LO, Singapore (SG); Chin Siong CHENG, Singapore (SG)

(73) Assignee: STMicroelectronics International N.V., Geneva (CH)

(21) Appl. No.: 19/386,500

(22) Filed: Nov. 12, 2025

Related U.S. Application Data
(60) Provisional application No. 63/727,845, filed on Dec. 4, 2024.

(51) Int. Cl. H01L 21/3065; H01L 21/762

(52) U.S. Cl. CPC H10P 50/244; H10W 10/014; H10W 10/17

(57) ABSTRACT

A process is provided for filling a high aspect ratio trench extending into the upper surface of a semiconductor substrate. The process includes a first filling phase which forms a conformal layer that only partially fills the trench and extends over the upper surface of the semiconductor substrate. An etch back is then performed to recess the portion of the conformal layer extending over the upper surface of the semiconductor substrate and form a funnel-shaped opening at the top of the trench. The process then further includes a second filling phase which forms a filling layer that fills the remainder of the trench including the funnel-shaped opening and extends over the upper surface of the semiconductor substrate. A further etch back is then performed to recess the portion of the filling layer extending over the upper surface of the semiconductor substrate and flatten an upper surface of the filled trench.

### CROSS REFERENCE TO RELATED APPLICATIONS

This application claims priority from U.S. Provisional Application for Patent No. 63/727,845, filed Dec. 4, 2024, the content of which is incorporated herein by reference.

### TECHNICAL FIELD

The present invention generally relates to a process for filling a high aspect ratio trench in a semiconductor substrate.

### BACKGROUND

The rapid alternating process (RAP) or Bosch process are methods well known to those skilled in the art for performing deep silicon etching in the formation of high aspect ratio trenches. These processes are characterized by the repeated use of alternating etching and deposition cycles which result in the formation of “scallops” 10 in the sidewalls of the etched trench 12 as shown in FIG. 1 (where reference 14 is a semiconductor, for example silicon, substrate, and reference 16 is a hard mask with an opening defining the location wherein the trench is to be etched). These scallops 10 are a direct result of the repeated alternating etching and deposition cycles (Note: the size and shape of the scalloped features as shown in the figures is exaggerated).

The trench 12 is then filled with a material selected dependent on the circuit application. For example, for forming a deep trench isolation (DTI) structure, the trench is filled with an insulating material 20 such as an oxide as shown in FIG. 2A (where FIG. 3A shows a corresponding scanning electron microscope (SEM) cross-sectional image). Alternatively, for another form of deep trench isolation (DTI) structure, the sidewalls and bottom of the trench are covered by an insulating liner 22 made of an oxide and the trench is filled with a highly resistive material 24 such as undoped polysilicon as shown in FIG. 2B (where FIG. 3B shows a corresponding scanning electron microscope (SEM) cross-sectional image). In yet another example for forming a trench super-junction type power transistor, the trench is filled with an epitaxial material 26 doped opposite to the substrate 14 as shown in FIG. 2C.

Due to the negative slope profile of the trench 12 near the top of the trench and the high aspect ratio of the trench, there is a high risk of void 30 formation when filling the trench. These voids 30, especially when located near the top of the trench 12, can generate a high level of mechanical stress induced during subsequent high temperature annealing processes. As a result, a warpage or bowing of the semiconductor wafer can occur, and this can adversely affect accurate performance of subsequent wafer processing operations.

Additionally, if the voids 30 are too close to the top of the trench 12, there is a risk of exposing (i.e., opening) the voids during subsequent etching or recessing processes. This is a concern because undesired material, such as a metal, can then fill the voids.

The presence of voids 30 in the epitaxial fill material 26 as shown in FIG. 2C can also have adverse effects on the charge balance, electric field and breakdown voltage of the trench super-junction type power transistor.

The filling of the trench 12 can also result in the formation of a topological depression 32 at the upper surface of the wafer. The high topological difference at the trench locations can have an adverse effect on wafer processing due to misalignment.

There is accordingly a need in the art to provide an improved and cost-effective method for filling high aspect ratio trenches formed in a semiconductor substrate.

### SUMMARY

In an embodiment, a method comprises: forming a high aspect ratio trench extending into a semiconductor substrate from an upper surface; in a first filling phase, forming a conformal layer made of a fill material that only partially fills the high aspect ratio trench and extends over the upper surface of the semiconductor substrate; performing a first etch back to recess a portion of the conformal layer which extends over the upper surface of the semiconductor substrate and form a funnel-shaped opening at a top of the trench; in a second filling phase, forming a filling layer, also made of the fill material, that fills a remainder of the trench including the funnel-shaped opening and extends over the upper surface of the semiconductor substrate; and performing a second etch back to recess a portion of the filling layer which extends over the upper surface of the semiconductor substrate to a level substantially coplanar with the upper surface of the semiconductor substrate.

In an embodiment, a method comprises: forming a high aspect ratio trench extending into a semiconductor substrate from an upper surface; lining the upper surface of the semiconductor substrate and sidewalls and a bottom of the high aspect ratio trench with an insulating liner; in a first filling phase, forming a conformal layer in contact with the oxide liner, wherein the conformal layer is made of a fill material, said conformal layer only partially filling the high aspect ratio trench and extending over the upper surface of the semiconductor substrate; performing a first etch back to recess a portion of the conformal layer which extends over the upper surface of the semiconductor substrate and form a funnel-shaped opening at a top of the trench; in a second filling phase, forming a filling layer in contact with the conformal layer, wherein the filling layer is also made of the fill material, said filling layer completely filling a remainder of the trench including the funnel-shaped opening and extending over the upper surface of the semiconductor substrate; and performing a second etch back to recess a portion of the filling layer which extends over the upper surface of the semiconductor substrate to a level substantially coplanar with the upper surface of the semiconductor substrate.

In an embodiment, a method comprises: forming a high aspect ratio trench extending into a semiconductor substrate from an upper surface; thermally oxidizing the upper surface of the semiconductor substrate and sidewalls and a bottom of the high aspect ratio trench with an insulating liner; removing the insulating liner to expose the semiconductor substrate; in a first filling phase, forming a conformal layer by epitaxial growth from the exposed semiconductor substrate, wherein the conformal layer is made of a semiconductor material, said conformal layer only partially filling the high aspect ratio trench and extending over the upper surface of the semiconductor substrate; performing a first etch back to recess a portion of the conformal layer which extends over the upper surface of the semiconductor substrate and form a funnel-shaped opening at a top of the trench; in a second filling phase, forming a filling layer by epitaxial growth from the conformal layer, wherein the filling layer is also made of the semiconductor material, said filling layer completely filling a remainder of the trench including the funnel-shaped opening and extending over the upper surface of the semiconductor substrate; and performing a second etch back to recess a portion of the filling layer which extends over the upper surface of the semiconductor substrate to a level substantially coplanar with the upper surface of the semiconductor substrate.

### BRIEF DESCRIPTION OF THE DRAWINGS

For a better understanding of the embodiments, reference will now be made by way of example only to the accompanying figures in which:

FIG. 1 illustrates a cross section of a trench formed using a Bosch process showing the presence of scalloped sidewall surface roughness;

FIGS. 2A-2C show cross-sectional views of a high aspect ratio trench formed by the Bosch process and incompletely filled with different materials and trench center void formation;

FIGS. 3A-3B are scanning electron microscope (SEM) cross-sectional images of filled trenches corresponding to FIGS. 2A-2B;

FIGS. 4A-4H illustrate steps in an improved process for forming and filling a high aspect ratio trench; and

FIG. 5 is a SEM cross-sectional image of the filled trench corresponding to FIG. 4H.

### DETAILED DESCRIPTION

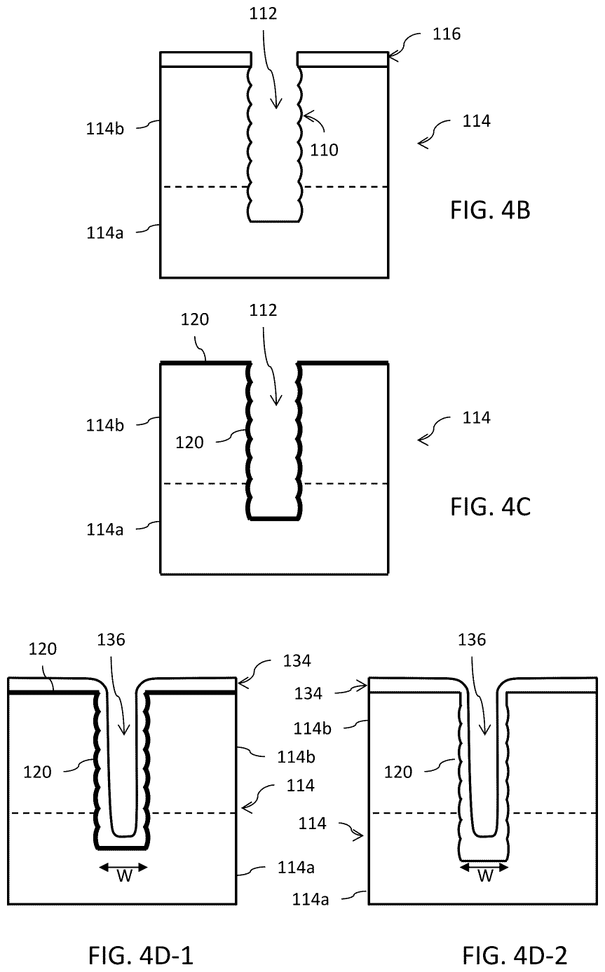

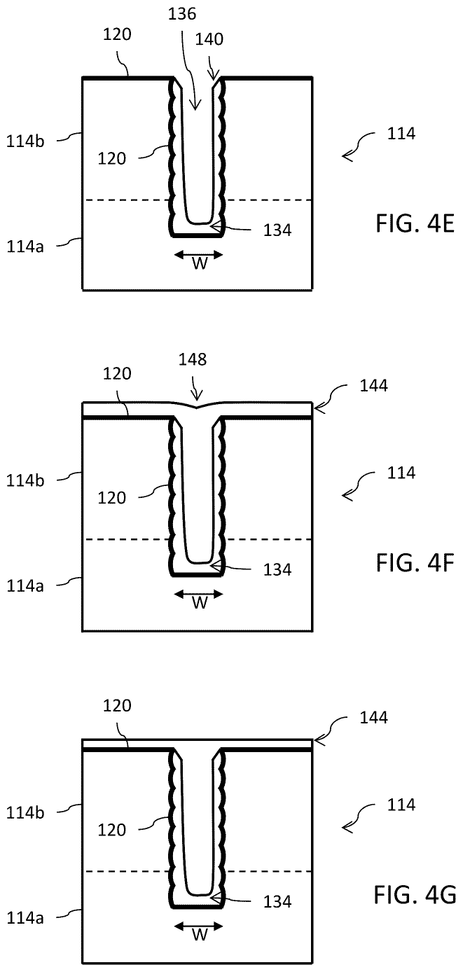

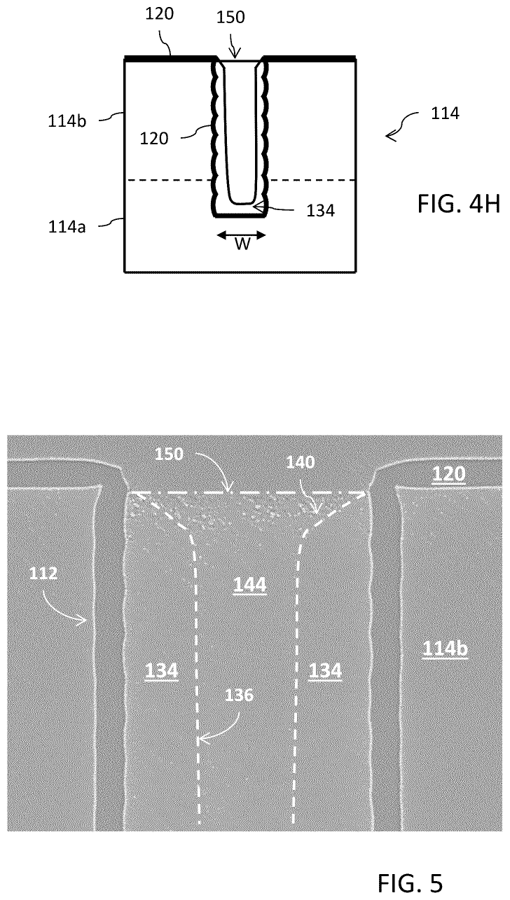

Reference is made to FIGS. 4A-4H which illustrate steps in process for forming and filling a high aspect ratio trench.

FIG. 4A—a hard mask 116 is formed on the upper surface of a semiconductor (for example, silicon) substrate 114 and patterned to include a mask opening 118 at the location where it is desired to form a trench. The substrate 114 may, for example, comprise a silicon substrate layer 114a and an overlying epitaxial layer 114b.

FIG. 4B—using a rapid alternating process (RAP), or Bosch etch process, as is well known to those skilled in the art, repeated alternating etching and deposition cycles are performed to open a trench 112 in the substrate 114 to a depth which, for example, passes completely through the epitaxial layer 114b and partially into the substrate layer 114a. It is noted that the RAP/Bosch etch process produces a trench sidewall surface roughness defined by scalloped features 110 (Note: the size and shape of the scalloped features as shown in the figures is exaggerated). The trench 112 has a high aspect ratio which, in the context of this disclosure and the claims, is understood to mean and refer to a ratio that is greater than or equal to 10:1 (depth: width).

FIG. 4C—a thermal oxidation is performed to oxidize the upper surface of the substrate 114 and the sidewalls and bottom of the trench 112 forming an oxide layer 120 that lines the inside of the trench 112.

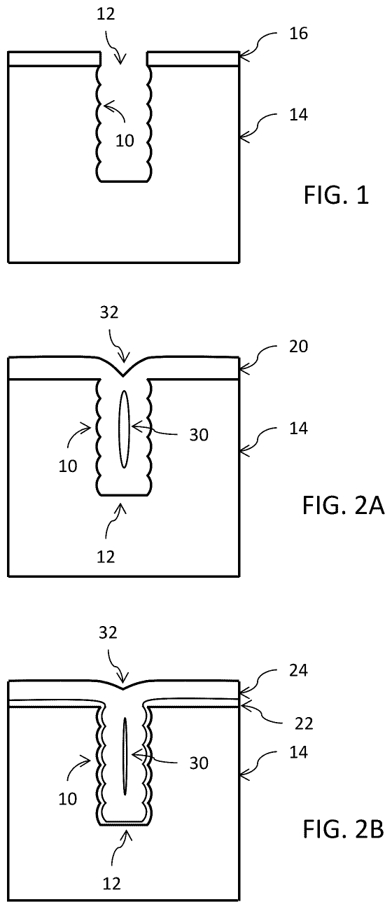

FIG. 4D-1—a conformal layer 134 of a desired material for filling the trench 112 is then provided on the oxide layer 120 during a first filling phase. This conformal layer 134 partially fills the trench 112 leaving an opening 136. The conformal layer 134 may comprise a deposited, for example using a low pressure chemical vapor deposition (LPCVD), insulating material such as an oxide or a highly resistive material such as an undoped polysilicon material.

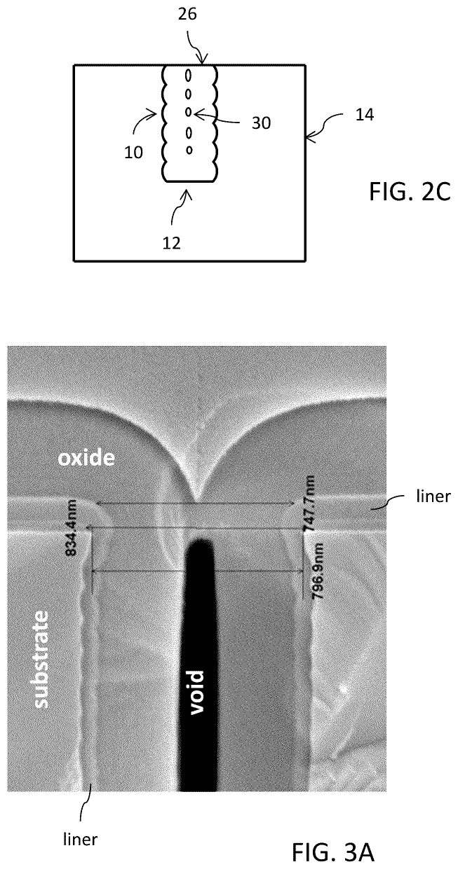

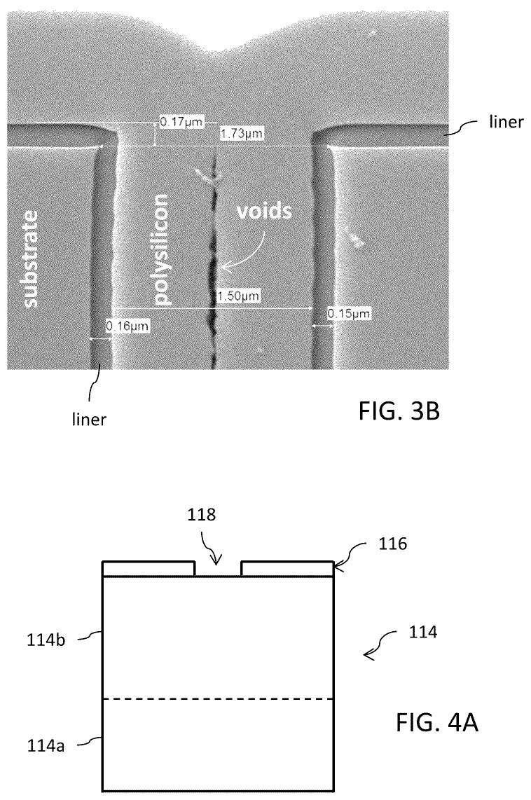

Alternatively, the conformal layer 134 may comprise a semiconductor material that is epitaxially grown from the semiconductor material of the substrate (in which case the oxide layer 120 lining the trench sidewalls and bottom is selectively removed to expose the semiconductor substrate prior to performing the epitaxial growth). See, FIG. 4D-2. The removal of the oxide layer 120 may provide for a smoothing of the scallop shape at the sidewalls of the trench.

A thickness of the conformal layer 134 is selected to ensure that the trench 112 is not substantially or completely filled. For example, the conformal layer 134 may have a thickness that is between 25-35% of the width W of the trench 114 so as to leave the opening 136.

Note: for the remaining description of the process, the configuration of the trench including the oxide liner 120 as shown in FIG. 4D-1 is utilized, but it will be understood that the process steps are equally applicable to the implementation shown in FIG. 4D-2 for the trench which does not include liner 120.

FIG. 4E—an etch back (for example of anisotropic type) is then performed to recess the portion of the conformal layer 134 located over the upper surface of the substrate. The etch back may, for example, comprise a poly etch back using Cl₂/HBr/HeO₂ chemistry, where the etch process is controlled by endpoint and followed by a defined over etch. This etch back may, for example, be stopped when the oxide layer 120 on the upper surface of the substrate 112, if present, is reached. The etch back will also remove a portion of the conformal layer 134 within the trench near the upper surface of the substrate 112 forming a tapered funnel-shaped opening 140 at the top of the opening 136 due to the anisotropic properties of the etch. The surface of the tapered opening 140 may, generally speaking, be defined by the surface of an up-side-down truncated cone.

FIG. 4F—a conformal layer 144 of the desired material for filling the trench 112 is then provided on the oxide layer 120 (or on the upper surface of layer 114b in the FIG. 4D-2 implementation) at the upper surface of the substrate 112 and on the conformal layer 134 located within the trench 112 during a second filling phase. The presence of the tapered opening 140 near the top of the trench 112 supports filling of the opening 136 without formation of voids (compared to FIGS. 2A-2C, reference 30). Additionally, the partial filling of the trench with conformal layer 134 first before filling with conformal layer 144 results in a less severe topological depression 148 at the upper surface of the semiconductor wafer (compared to FIGS. 2A-2C, reference 32). The conformal layer 144 may comprise a deposited insulating material such as an oxide material matching the material of layer 134. The conformal layer 144 may comprise a deposited highly resistive material such as an undoped polysilicon material matching the material of layer 134. These depositions may, for example, be accomplished using a low pressure chemical vapor deposition (LPCVD) process.

In the alternative implementation associated the structure of FIG. 4D-2, the conformal layer 144 may comprise a semiconductor material matching the material of layer 134 that is epitaxially grown from the semiconductor material of layer 134.

A thickness of the conformal layer 144 is selected to ensure that the remaining openings 136, 140 in the trench 112 are completely filled. For example, the conformal layer 144 may have a thickness that is about two times (plus/minus 10%) the thickness of the conformal layer 134.

FIG. 4G—a polishing operation is then performed to planarize the upper surface of the conformal layer 144 over the substrate 112. This polishing operation may, for example, comprise a chemical-mechanical polishing (CMP).

FIG. 4H—an etch back (for example of anisotropic type) is then performed to recess the conformal layer 144 to a surface level 150 substantially coplanar with the upper surface of the substrate 112. In this context, substantially coplanar means that the upper surface of the substrate 112 and the surface level 150 are at or near the same elevation subject to the tolerances of the etch stopping control limits of the manufacturing process used for the etch back operation. As an example, substantially coplanar means that any surface offset difference in a vertical direction is less than or equal to 0.1 μm. The etch back may, for example, comprise a poly etch back using Cl₂/HBr/HeO₂ chemistry, where the etch process is controlled by endpoint and followed by a defined over etch. The combination of the polishing operation of FIG. 4G and the etch back of FIG. 4H provides an upper surface of the filled trench that is flattened, for example to a level coplanar with the upper surface of the substrate, thus obviating concerns with presence of a high topological difference at trench locations that are a problem with previous solutions like that shown in FIG. 2A-2B.

FIG. 5 is an annotated SEM cross-sectional image corresponding to FIG. 4H. Because the material conformal layers 134, 144 is the same material, a distinction between the two layers is not readily visible in the SEM image. The annotated dotted lines show the general location differentiating the layers 134, 144.

Example: for a trench 112 having a width in a range of 0.5 to 2 μm and a depth in a range of 5 to 40 μm (in other words, a trench having an aspect ratio in a range of about 10:1 to 20:1), the conformal layer 134 may have a thickness in a range of 2 to 10 kÅ and the conformal layer 144 may have a thickness in a range of 4 to 20 kÅ. It will be noted that the process of FIG. 4A for forming the trench provides a trench having a highly vertical sidewall profile. The etch back of FIG. 4E recesses the full thickness of layer 134 from above the substrate and forms the tapered funnel-shaped opening 140. The polishing operation of FIG. 4G thins the layer 144 above the substrate by about one-half its thickness. The etch back of FIG. 4H recesses the remaining thickness of layer 144 from above the substrate and forms the coplanar upper surface with substrate 112. The filled trench exhibits no voids at least in the upper half of the trench depth.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

What is claimed is:

1. A method, comprising:
forming a high aspect ratio trench extending into a semiconductor substrate from an upper surface;
in a first filling phase, forming a conformal layer made of a fill material that only partially fills the high aspect ratio trench and extends over the upper surface of the semiconductor substrate;
performing a first etch back to recess a portion of the conformal layer which extends over the upper surface of the semiconductor substrate and form a funnel-shaped opening at a top of the trench;
in a second filling phase, forming a filling layer, also made of the fill material, that fills a remainder of the trench including the funnel-shaped opening and extends over the upper surface of the semiconductor substrate; and
performing a second etch back to recess a portion of the filling layer which extends over the upper surface of the semiconductor substrate to a level substantially coplanar with the upper surface of the semiconductor substrate.

2. The method of claim 1, wherein forming a high aspect ratio trench comprises one of a Bosch etching process or a rapid alternating process (RAP) etching for trench formation.

3. The method of claim 1, wherein the high aspect ratio trench has an aspect ratio greater than or equal to 10:1.

4. The method of claim 1, further comprising, after the second filling phase and before the second etch back, performing a polishing of an upper surface of the filling layer.

5. The method of claim 1, wherein the conformal layer has a first thickness and the filling layer has a second thickness greater than the first thickness.

6. The method of claim 5, wherein the second thickness is about two times the first thickness.

7. The method of claim 5, wherein the first thickness is about one-third a width of the high aspect ratio trench, and the second thickness is about two-thirds the width of the high aspect ratio trench.

8. The method of claim 1, wherein the semiconductor substrate comprises a silicon substrate layer and an overlying epitaxial layer, and wherein the high aspect ratio trench extends completely through the overlying epitaxial layer and partially into the silicon substrate layer.

9. The method of claim 1, further comprising, before the first filling phase, thermally oxidizing to form an oxide liner on the upper surface of the semiconductor substrate and sidewalls and a bottom of the high aspect ratio trench.

10. The method of claim 9, further comprising, removing the oxide liner before the first filling phase.

11. The method of claim 10, wherein the filling material in the first filling phase is a semiconductor material grown from the semiconductor substrate.

12. The method of claim 9, wherein the filling material in the first filling phase is an oxide insulating material in contact with the oxide liner.

13. The method of claim 9, wherein the filling material in the first filling phase is an undoped polysilicon material in contact with the oxide liner.

14. A method, comprising:
forming a high aspect ratio trench extending into a semiconductor substrate from an upper surface;
lining the upper surface of the semiconductor substrate and sidewalls and a bottom of the high aspect ratio trench with an insulating liner;
in a first filling phase, forming a conformal layer in contact with the oxide liner, wherein the conformal layer is made of a fill material, said conformal layer only partially filling the high aspect ratio trench and extending over the upper surface of the semiconductor substrate;
performing a first etch back to recess a portion of the conformal layer which extends over the upper surface of the semiconductor substrate and form a funnel-shaped opening at a top of the trench;
in a second filling phase, forming a filling layer in contact with the conformal layer, wherein the filling layer is also made of the fill material, said filling layer completely filling a remainder of the trench including the funnel-shaped opening and extending over the upper surface of the semiconductor substrate; and
performing a second etch back to recess a portion of the filling layer which extends over the upper surface of the semiconductor substrate to a level substantially coplanar with the upper surface of the semiconductor substrate.

15. The method of claim 14, wherein the filling material in the first filling phase is an oxide insulating material.

16. The method of claim 14, wherein the filling material in the first filling phase is an undoped polysilicon material.

17. The method of claim 14, wherein the high aspect ratio trench has an aspect ratio greater than or equal to 10:1.

18. The method of claim 14, wherein the insulating liner is formed by thermally oxidizing the semiconductor substrate.

19. A method, comprising:
forming a high aspect ratio trench extending into a semiconductor substrate from an upper surface;
thermally oxidizing the upper surface of the semiconductor substrate and sidewalls and a bottom of the high aspect ratio trench with an insulating liner;
removing the insulating liner to expose the semiconductor substrate;
in a first filling phase, forming a conformal layer by epitaxial growth from the exposed semiconductor substrate, wherein the conformal layer is made of a semiconductor material, said conformal layer only partially filling the high aspect ratio trench and extending over the upper surface of the semiconductor substrate;
performing a first etch back to recess a portion of the conformal layer which extends over the upper surface of the semiconductor substrate and form a funnel-shaped opening at a top of the trench;
in a second filling phase, forming a filling layer by epitaxial growth from the conformal layer, wherein the filling layer is also made of the semiconductor material, said filling layer completely filling a remainder of the trench including the funnel-shaped opening and extending over the upper surface of the semiconductor substrate; and
performing a second etch back to recess a portion of the filling layer which extends over the upper surface of the semiconductor substrate to a level substantially coplanar with the upper surface of the semiconductor substrate.

20. The method of claim 19, wherein the high aspect ratio trench has an aspect ratio greater than or equal to 10:1.
